(19) United States
(12) Patent Application Publication
(10) Pub. No.: US 2025/0015196 A1
(43) Pub. Date: Jan. 9, 2025

(54) THIN FILM TRANSISTOR AND ELECTRONIC DEVICE

(71) Applicants: Japan Display Inc., Tokyo (JP); IDEMITSU KOSAN CO., LTD., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Emi KAWASHIMA, Tokyo (JP); Yuki TSURUMA, Tokyo (JP); Daichi SASAKI, Tokyo (JP)

(73) Assignees: Japan Display Inc., Tokyo (JP); IDEMITSU KOSAN CO., LTD., Tokyo (JP)

(21) Appl. No.: 18/889,394

(22) Filed: Sep. 19, 2024

Related U.S. Application Data
(63) Continuation of application No. PCT/JP2023/006035, filed on Feb. 20, 2023.

(30) Foreign Application Priority Data
Mar. 30, 2022 (JP) 2022-057449

(51) Int. Cl. H01L 29/786; H01L 29/66

(52) U.S. Cl. CPC H01L 29/7869; H01L 29/66969; H01L 29/78633; H01L 29/78648; H01L 29/78696

(57) ABSTRACT

A thin film transistor includes a metal oxide layer over the substrate, an oxide semiconductor layer having crystallinity in contact with the metal oxide layer, a gate electrode overlapping the oxide semiconductor layer, and an insulating layer between the oxide semiconductor layer and the gate electrode. The oxide semiconductor layer includes a plurality of crystal grains. Each of the plurality of crystal grains includes at least one of a crystal orientation <001>, a crystal orientation <101>, and a crystal orientation <111> obtained by an EBSD method. In occupancy rates of crystal orientations calculated based on measurement points having crystal orientations with a crystal orientation difference greater than or equal to 0 degrees and less than or equal to 15 degrees with respect to a normal direction of a surface of the substrate, an occupancy rate of the crystal orientation <001> is less than or equal to 5%.

### CROSS-REFERENCE TO RELATED APPLICATIONS

This application is a Continuation of International Patent Application No. PCT/JP2023/006035, filed on Feb. 20, 2023, which claims the benefit of priority to Japanese Patent Application No. 2022-057449, filed on Mar. 30, 2022, the entire contents of each are incorporated herein by reference.

### FIELD

An embodiment of the present invention relates to a thin film transistor including an oxide semiconductor film. Further, an embodiment of the present invention relates to an electronic device including the thin film transistor.

### BACKGROUND

In recent years, instead of a silicon semiconductor film using amorphous silicon, low-temperature polysilicon, and single-crystal silicon, a thin film transistor in which an oxide semiconductor film is used for a channel has been developed (for example, see Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The thin film transistor including an oxide semiconductor film has a simple structure and can be manufactured over a glass substrate by a low-temperature process, similar to a semiconductor device including an amorphous silicon film. Further, the thin film transistor including an oxide semiconductor film is known to have higher mobility than the thin film transistor including an amorphous silicon film.

### SUMMARY

A thin film transistor according to an embodiment of the present invention includes a substrate, a metal oxide layer over the substrate, an oxide semiconductor layer having crystallinity in contact with the metal oxide layer, a gate electrode overlapping the oxide semiconductor layer, and an insulating layer between the oxide semiconductor layer and the gate electrode. The oxide semiconductor layer includes a plurality of crystal grains. Each of the plurality of crystal grains includes at least one of a crystal orientation <001>, a crystal orientation <101>, and a crystal orientation <111> obtained by an electron backscatter diffraction (EBSD) method.

An electronic device according to an embodiment of the present invention includes the thin film transistor.

### BRIEF DESCRIPTION OF DRAWINGS

FIG. 1 is an IPF map of an oxide semiconductor film (Example 1) according to an embodiment of the present invention.

FIG. 2 is an IPF map of an oxide semiconductor film (Example 1) according to an embodiment of the present invention.

FIG. 3 is a map showing a distribution of GOS in an oxide semiconductor film (Example 1) according to an embodiment of the present invention.

FIG. 4 is an IPF map of an oxide semiconductor film (Example 2) according to an embodiment of the present invention.

FIG. 5 is an IPF map of an oxide semiconductor film (Example 2) according to an embodiment of the present invention.

FIG. 6 is a map showing a distribution of GOS in an oxide semiconductor film (Example 2) according to an embodiment of the present invention.

FIG. 7 is a cross-sectional view showing an outline of a thin film transistor according to an embodiment of the present invention.

FIG. 8 is a plan view showing an outline of a thin film transistor according to an embodiment of the present invention.

FIG. 9 is a flowchart showing a method for manufacturing a thin film transistor according to an embodiment of the present invention.

FIG. 10 is a cross-sectional view showing a method for manufacturing a thin film transistor according to an embodiment of the present invention.

FIG. 11 is a cross-sectional view showing a method for manufacturing a thin film transistor according to an embodiment of the present invention.

FIG. 12 is a cross-sectional view showing a method for manufacturing a thin film transistor according to an embodiment of the present invention.

FIG. 13 is a cross-sectional view showing a method for manufacturing a thin film transistor according to an embodiment of the present invention.

FIG. 14 is a cross-sectional view showing a method for manufacturing a thin film transistor according to an embodiment of the present invention.

FIG. 15 is a cross-sectional view showing a method for manufacturing a thin film transistor according to an embodiment of the present invention.

FIG. 16 is a cross-sectional view showing a method for manufacturing a thin film transistor according to an embodiment of the present invention.

FIG. 17 is a cross-sectional view showing a method for manufacturing a thin film transistor according to an embodiment of the present invention.

FIG. 18 is a cross-sectional STEM image of a thin film transistor according to an embodiment of the present invention.

FIG. 19 is a cross-sectional STEM image of a thin film transistor according to an embodiment of the present invention.

FIG. 20 is a schematic diagram showing an electronic device according to an embodiment of the present invention.

FIG. 21 is an IPF map of a conventional oxide semiconductor film (Comparative Example).

FIG. 22 is an IPF map of a conventional oxide semiconductor film (Comparative Example).

FIG. 23 is a map showing a distribution of a GOS in a conventional oxide semiconductor film (Comparative Example).

### DESCRIPTION OF EMBODIMENTS

The field-effect mobility of a thin film transistor including a conventional oxide semiconductor film is not so high even when an oxide semiconductor film having crystallinity is used. Therefore, it has been desired to improve the crystal structure of the oxide semiconductor film used in the thin film transistor and thereby improve the field-effect mobility of the thin film transistor.

In view of the above problems, an embodiment of the present invention can provide a thin film transistor including an oxide semiconductor film having a novel crystal structure. Further, an embodiment of the present invention can provide an electronic device including the thin film transistor.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the present specification, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is different from that shown in the drawings. In the following explanation, for example, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a transistor and a pixel electrode do not overlap in a plan view when expressed as “a pixel electrode over a transistor.” On the other hand, the expression “a pixel electrode vertically over a transistor” means a positional relationship in which the transistor and the pixel electrode overlap in a plan view.

In the present specification, the terms “film” and “layer” can be optionally interchanged with one another.

In the present specification, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, although a liquid crystal display device including a liquid crystal layer and an organic EL display device including an organic EL layer are exemplified as a display device in the following embodiments, the structure according to the present embodiment can be applied to a display device including the other electro-optic layers described above.

In the present specification, the expression “α includes A, B, or C,” “α includes any of A, B, or C,” “α includes one selected from a group consisting of A, B and C,” and the like does not exclude the case where α includes a plurality of combinations of A to C unless otherwise specified. Further, these expressions do not exclude the case where α includes other components.

In addition, the following embodiments may be combined with each other as long as there is no technical contradiction.

### First Embodiment

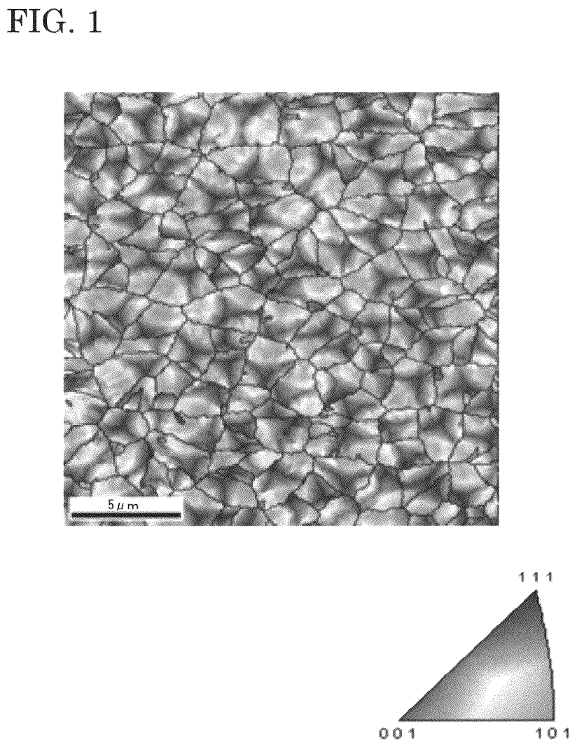

An oxide semiconductor film according to an embodiment of the present invention is described with reference to FIGS. 1 to 6.

### 1. COMPOSITION OF OXIDE SEMICONDUCTOR FILM

The oxide semiconductor film according to the present embodiment contains indium (In) and a metal element (M) other than indium. In the composition ratio of the oxide semiconductor film, the atomic ratio of indium and the metal element other than indium preferably satisfies formula (1). In other words, it is preferable that the ratio of indium to all metal elements including indium in the oxide semiconductor film is greater than or equal to 50%. When the ratio of indium increases, the oxide semiconductor film having crystallinity can be formed. Further, it is preferable that the crystal structure of the oxide semiconductor film has a bixbyite structure. When the ratio of indium increases, the oxide semiconductor film having a bixbyite structure can be formed.

$$\begin{matrix}[ Equation 1 ] & \\ 0.01 < \frac{[ M ]}{[ In ] + [ M ]} < 0.5 & ( 1 )\end{matrix}$$

In addition, the metal element other than indium is not limited to one type of metal element. A plurality of types of metal elements may be contained in the oxide semiconductor film as the metal elements other than indium.

Although details of a method for manufacturing the oxide semiconductor film are described later, the oxide semiconductor film can be formed by a sputtering method. The composition of the oxide semiconductor film formed by sputtering depends on the composition of the sputtering target. When the sputtering target has the above-described composition, the oxide semiconductor film without composition deviation of metal elements can be formed by sputtering. Therefore, the composition of metal elements (e.g., indium and other metal elements) of the oxide semiconductor film may be equivalent to the composition of metal elements of the sputtering target. For example, the composition of metal elements of the oxide semiconductor film can be specified based on the composition of metal elements of the sputtering target. In addition, oxygen contained in the oxide semiconductor film is not limited thereto because it changes depending on the process conditions of sputtering.

Alternatively, the composition of metal elements in the oxide semiconductor film can be specified by X-ray fluorescence analysis, EPMA (Electron Probe Micro Analyzer) analysis, etc. Further, since the oxide semiconductor film has crystallinity, the composition of metal elements in the oxide semiconductor film can also be specified from the crystal structure and lattice constant by X-ray diffraction (XRD).

### 2. CRYSTAL STRUCTURE OF OXIDE SEMICONDUCTOR FILM

The oxide semiconductor film according to the present embodiment has crystallinity. Although the crystal structure of the oxide semiconductor film is not limited to a specific structure, it is preferable that the crystal structure is a bixbyite structure. The crystal structure of the oxide semiconductor film can be specified by an XRD method or an electron beam diffraction method.

Further, the oxide semiconductor film according to the present embodiment includes a plurality of crystal grains. The inventors have found that the crystal grains of the oxide semiconductor film according to the present embodiment have features different from those of crystal grains of a conventional oxide semiconductor film. Specifically, the inventors have found that the oxide semiconductor film having a novel crystal structure includes crystal grains different from conventional crystal grains. The oxide semiconductor film having such a novel crystal structure can be measured by an electron backscatter diffraction (EBSD) method. Hereinafter, the measurement of the oxide semiconductor film by the EBSD method is described.

### 2-1. EBSD Method

The EBSD method is an analysis method in which an object to be measured is irradiated with an electron beam, and electron backscatter diffraction generated on each crystal plane of the crystal structure of the object to be measured is analyzed to measure the crystal structure in a measurement region of the object to be measured. The EBSD method can obtain information such as crystal grains or crystal orientations of the oxide semiconductor film in the measurement region by analyzing data obtained from an EBSD detector attached to a scanning electron microscope (SEM) or a transmission electron microscope (TEM).

### 2-2. IPF Map

An IPF (Inverse Pole Figure) map is an image in which crystal orientations are color-coded according to a predetermined color key. Since the measurement using the EBSD method can obtain information on crystal orientations, the IPF map can be created based on the obtained information on crystal orientations. In the IPF map, an area of each of the color-coded regions of the plurality of crystal orientations is obtained, and the ratio of each area to the total area of the measurement region (hereinafter, referred to as “occupancy rate”) is calculated and quantitatively compared.

The IPF map may be an image obtained by extracting data of measurement points whose crystal orientation differences with respect to the normal direction of a surface of a substrate (or a surface of the oxide semiconductor film) are within a predetermined range. For example, the predetermined range is greater than or equal to 0 degrees and less than or equal to 15 degrees. In the IPF map from which data of specific measurement points is extracted in this manner, measurement points having crystal orientations that are significantly inclined from the normal direction of the surface of the substrate are excluded, so that the crystal orientations that tend to be oriented among the plurality of crystal orientations can be made apparent. Therefore, in the IPF map from which data of specific measurement points is extracted, the occupancy rates of the plurality of crystal orientations can be compared, and the crystal orientations that tend to be oriented can be more clearly specified.

When the oxide semiconductor film according to the present embodiment has a bixbyite structure, the occupancy rates of the crystal orientation <101> and the crystal orientation <111> are larger than the occupancy rate of the crystal orientation <001> in the range of a crystal orientation difference from 0 degrees to 15 degrees with respect to the normal direction of the substrate surface. In other words, in the oxide semiconductor film according to the present embodiment, the occupancy rate of the crystal orientation <001> is significantly small, at less than or equal to 5%, which is a feature not seen in the conventional oxide semiconductor film. In the oxide semiconductor film according to the present embodiment, each of the occupancy rates of the crystal orientation <101> and the crystal orientation <111> is greater than or equal to 4 times, preferably greater than or equal to 10 times, and more preferably greater than or equal to 15 times the occupancy rate of the crystal orientation <001>. On the other hand, in the conventional oxide semiconductor film, each of the occupancy rates of the crystal orientation <101> and the crystal orientation <111> does not exceed 4 times the occupancy rate of the crystal orientation <001>. Further, in the oxide semiconductor film according to the present embodiment, the total occupancy rate of the crystal orientation <101> and the crystal orientation <111> is greater than or equal to 10 times, preferably greater than or equal to 20 times, and more preferably greater than or equal to 30 times the occupancy rate of the crystal orientation <001>. On the other hand, in the conventional oxide semiconductor film, the total occupancy rate of the crystal orientation <101> and the crystal orientation <111> is less than 10 times the occupancy rate of the crystal orientation <001>.

Further, the ratio of the occupancy rate of the crystal orientation <101> to the occupancy rate of the crystal orientation <111> is greater than or equal to 0.7 and less than or equal to 1.5.

Here, the crystal orientation <001> represents [001] and its equivalents [100] and [010]. The crystal orientation <101> represents [101] and its equivalents [110] and [011]. The crystal orientation <111> represents [111]. Further, in each orientation, “1” may be “−1” and is considered to be an axis equivalent to each orientation.

In addition, crystal orientations include <hk0> (h≠k, h and k are natural numbers), <hhl> (h≠l, h and l are natural numbers), and <hkl> (h≠k≠l, h, k, and l are natural numbers) other than <001>, <101>, and <111>.

### 2-3. Crystal Grain

A crystal grain is a crystalline region surrounded by a crystal grain boundary. Since the EBSD method obtains information about the crystal orientation, the crystal grain boundary can be defined based on the crystal orientation. In general, when the crystal orientation difference between two adjacent measurement points exceeds 5 degrees, it is defined that a crystal grain boundary exists between them. Therefore, the above definition is also applied to the oxide semiconductor film according to the present embodiment.

The oxide semiconductor film according to the present embodiment includes a plurality of regions with different crystal orientations in one crystal grain. For example, when the oxide semiconductor film according to the present embodiment has a bixbyite structure, one crystal grain including at least two of the crystal orientations <001>, <101>, and <111> are present. It is considered that a large change in crystal orientation is occurred in this crystal grain, and is a feature not seen in the conventional oxide semiconductor film.

### 2-4. Crystal Grain Size

A crystal grain size is a value representing the size of a crystal grain. Since the area S of a crystal grain can be calculated in the EBSD method, the diameter of a circle corresponding to the area S is defined as the crystal grain size d.

### 2-5. Average Crystal Grain Size

An average crystal grain size is an average value of crystal grain sizes of a plurality of crystal grains. Since the oxide semiconductor film according to the present embodiment includes a plurality of crystal grains, the oxide semiconductor film can be evaluated using the average crystal grain size. The average crystal grain size d_{AVE} is calculated by formula (2). Here, Aⱼ is the area ratio of the j-th crystal grain (the ratio of the area of the crystal grain to the area of the entire EBSD measurement region (the measurement region)), dⱼ is the crystal grain size of the j-th crystal grain, and N is the number of crystal grains. As shown in formula (2), the average crystal grain size d_{AVE} is the average area in the measurement region weighted by the area of the crystal grains. When the average crystal grain size d_{AVE} is large, it can be said that many crystal grains with a large crystal grain size are present in the oxide semiconductor film.

$$\begin{matrix}[ Equation 2 ] & \\ {d}_{AVE} = {\sum }_{j = 1}^{N} {A}_{j} * {d}_{j} & ( 2 )\end{matrix}$$

The crystal grains in the oxide semiconductor film according to the present embodiment have a larger average crystal grain size than the crystal grains in the conventional oxide semiconductor film. For example, the average crystal grain size of the crystal grains in the oxide semiconductor film according to the present embodiment is greater than or equal to 1 μm, preferably greater than or equal to 1.3 μm, and more preferably greater than or equal to 1.5 μm.

### 2-6. Maximum Crystal Grain Size

A maximum crystal grain size is a maximum value of the crystal grain size of a plurality of crystal grains. The crystal grains of the oxide semiconductor film according to the present embodiment have a larger maximum crystal grain size than the crystal grains of the conventional oxide semiconductor film. For example, the maximum crystal grain size of the crystal grains in the oxide semiconductor film according to the present embodiment is greater than or equal to 1 μm, preferably greater than or equal to 2 μm, and more preferably greater than or equal to 3 μm.

### 2-7. GOS

A GOS (Grain Orientation Spread) is a value representing the crystal orientation difference in a crystal grain. The GOS is calculated by the formula (3). That is, the GOS is a value obtained by dividing the difference between the crystal orientation θi of the i-th measurement point in the crystal grain and the average crystal orientation θ_{AVE} of the n measurement points in the crystal grain by the n measurement points in the crystal grain. In other words, the GOS is a value obtained by averaging the crystal orientation in the crystal grain. Since the GOS represents the magnitude of strain in the crystal grain, it can be said that the strain in the crystal grain is large when the GOS is large.

$$\begin{matrix}[ Equation 3 ] & \\ GOS = {\sum }_{i = 1}^{n} ( {θ}_{i} - {θ}_{AVE} ) / n & ( 3 )\end{matrix}$$

### 2-8. Average GOS

An average GOS is an average value of the GOS of a plurality of crystal grains. Since the oxide semiconductor film according to the present embodiment includes the plurality of crystal grains, the oxide semiconductor film can be evaluated using the average GOS. The average GOS GOS_{AVE} is calculated by formula (4). Here, Aⱼ is the area ratio of the j-th crystal grain, GOSⱼ is the GOS of the j-th crystal grain, and N is the number of crystal grains. As shown in formula (4), the average GOS GOS_{AVE} is the average area in the measurement region weighted by the area of the crystal grains. When the average GOS GOS_{AVE} is large, it can be said that the oxide semiconductor film includes many crystal grains whose crystal orientation changes significantly.

$$\begin{matrix}[ Equation 4 ] & \\ {GOS}_{AVE} = {\sum }_{j = 1}^{N} {A}_{j} * {GOS}_{j} & ( 4 )\end{matrix}$$

As described above, the oxide semiconductor film according to the present embodiment includes crystal grains whose crystal orientation changes significantly, and the number of such crystal grains is reflected as the average GOS. In the oxide semiconductor film according to the present embodiment, the average GOS is greater than or equal to 5 degrees. Since the average GOS of the conventional oxide semiconductor film is less than or equal to 1 degree, a large average GOS is also one of the features of the oxide semiconductor film according to the present embodiment.

In the conventional oxide semiconductor film, when the crystal orientation in the crystal grain changes significantly, the crystal grain has large strain and the crystal growth of the crystal grain is inhibited. Therefore, in the conventional oxide semiconductor film, the change in the crystal orientation in the crystal grain is small, and the average crystal grain size or the maximum crystal grain size is also small. In contrast, large crystal grains are formed despite the large change in the crystal orientation in the crystal grain in the oxide semiconductor film according to the present embodiment, and the oxide semiconductor film according to the present embodiment has a larger average crystal grain size or a larger maximum crystal grain size than the conventional oxide semiconductor film. Further, in general, when the change in the crystal orientation in the crystal grain is large, lattice defects are likely to be generated, and the insulating properties (or semiconductor properties) of the oxide semiconductor film are deteriorated. However, in the oxide semiconductor film according to the present embodiment, the amount of oxygen deficiencies in the film after heat treatment is suppressed by generating crystal nuclei of a specific crystal orientation by optimizing the sputtering film formation conditions. Thus, the insulating properties are not deteriorated, and a thin film transistor using the oxide semiconductor film for a channel has excellent electrical properties with high mobility.

In addition, the measurement of the crystal structure of the oxide semiconductor film according to the present embodiment is not limited to the EBSD method. The crystal orientation or the change in the crystal orientation in the crystal grains may be measured using a measurement method other than the EBSD method.

### 3. MANUFACTURING METHOD OF OXIDE SEMICONDUCTOR FILM

The oxide semiconductor film according to the present embodiment is manufactured by a sputtering process and an annealing process.

In the sputtering process, an oxide semiconductor film is deposited in contact with a metal oxide film. When the oxide semiconductor film according to the present embodiment is deposited in contact with the metal oxide film, the crystallinity of the oxide semiconductor film can be improved. Therefore, the oxide semiconductor film is deposited over and in contact with the metal oxide film formed on a substrate, for example. Although details of the metal oxide film are described later, aluminum oxide is used for the metal oxide, for example.

It is preferable that the oxide semiconductor film after the sputtering process is a film with a small amount of crystalline components. In particular, it is preferable that the oxide semiconductor film is amorphous. In the film formation by sputtering, since ions generated in the plasma and atoms recoiled by the sputtering target collide with the substrate, the substrate temperature rises during the film deposition even when the substrate temperature at the start of sputtering is room temperature. When the substrate temperature rises during the film deposition, the oxide semiconductor film immediately after the film deposition includes microcrystals, and the subsequent annealing process tends to generate crystal grains with the crystal orientation <001>. Therefore, it is preferable to deposit the oxide semiconductor film while controlling the substrate temperature. For example, the substrate temperature is less than or equal to 100° C., preferably less than or equal to 70° C., and more preferably less than or equal to 50° C. The substrate temperature may be less than or equal to 30° C. For example, the substrate temperature can be controlled by cooling the substrate. Further, the oxide semiconductor film may be deposited at a film formation rate such that the substrate temperature does not exceed a reached temperature. Furthermore, the substrate temperature may be controlled by increasing the distance between the target and the substrate so that the substrate is not affected by the sputtering target.

A rigid substrate such as a glass substrate, a quartz substrate, or a sapphire substrate, or a flexible substrate such as a polyimide substrate, an acrylic substrate, a siloxane substrate, or a fluororesin substrate is used as the substrate on which the oxide semiconductor film is deposited. The substrate on which the oxide semiconductor film is deposited may be a substrate on which a silicon oxide (SiOₓ) film, a silicon oxynitride (SiOₓN_{y}) film, a silicon nitride (SiNₓ) film, a silicon nitride oxide (SiNₓO_{y}) film, an aluminum oxide (AlOₓ) film, an aluminum oxynitride (AlOₓN_{y}), an aluminum nitride oxide (AlNₓO_{y}), or an aluminum nitride (AlNₓ) film is formed.

Further, in the sputtering process, the oxide semiconductor film is deposited under the condition of an oxygen partial pressure less than or equal to 10%. When the oxygen partial pressure is high, the oxide semiconductor film immediately after the film deposition includes microcrystals due to excess oxygen in the oxide semiconductor film, and crystal grains with the crystal orientation <001> are likely to be generated by the subsequent annealing process. Therefore, it is preferable to deposit the oxide semiconductor film under the condition of a low oxygen partial pressure. For example, the oxygen partial pressure is greater than or equal to 2% and less than or equal to 10%, preferably greater than or equal to 3% and less than or equal to 8%, and more preferably greater than or equal to 3% and less than or equal to 6%.

In the annealing process, the oxide semiconductor film is crystallized. The annealing process is performed by holding a reached temperature for a predetermined time. The reached temperature is greater than or equal to 300° C. and less than or equal to 500° C., and preferably greater than or equal to 350° C. and less than or equal to 450° C. The holding time at the reached temperature is greater than or equal to 15 minutes and less than or equal to 120 minutes, and preferably greater than or equal to 30 minutes and less than or equal to 60minutes.

### 4. EXAMPLES

The oxide semiconductor film according to the present embodiment is described in more detail with reference to specific examples. In addition, the examples described below are some examples of the oxide semiconductor film according to the present embodiment, and the configuration of the oxide semiconductor according to the present embodiment is not limited to the configuration of the examples described below.

### 4-1. Manufacturing Method

### Example 1

In Example 1, the oxide semiconductor film according to the present embodiment was formed over the substrate provided with the aluminum oxide film using the above-described sputtering process and annealing process. In the sputtering process, the oxide semiconductor film was deposited on a glass substrate using a sputtering target in which indium greater than or equal to 70% in an atomic ratio to all metal elements was contained in the sintered body. The oxygen partial pressure during film deposition was 5.1%, and the substrate temperature during film deposition was controlled to be less than or equal to 100° C. Then, the annealing process was performed on the oxide semiconductor film in an air atmosphere. In the annealing process, the reached temperature was controlled to be 400° C., and was held for 30 minutes. The chemical composition of the oxide semiconductor film was similar to that of the sputtering target.

### Example 2

In Example 2, only the condition of the annealing process was changed, and the oxide semiconductor film according to the present embodiment was formed in the same manner as in Example 1. In the annealing process, the reached temperature was controlled to be 450° C., and was held for 60 minutes.

### Comparative Example

In the Comparative Example, the conventional oxide semiconductor film was formed on the substrate not provided with the aluminum oxide film using a conventional sputtering process and an annealing process. In the sputtering process, an oxide semiconductor film was deposited on a quartz substrate using a sputtering target in which indium greater than or equal to 70% in an atomic ratio to all metal elements was contained in the sintered body. The oxygen partial pressure during film deposition was 10.0%, and the substrate temperature during film deposition was not controlled. Then, the annealing process was performed on the oxide semiconductor film in an air atmosphere. In the annealing process, the reached temperature was controlled to be 450° C., and was held for 60 minutes. The chemical composition of the oxide semiconductor film was similar to that of the sputtering target.

The manufacturing conditions (deposition conditions and annealing conditions) of Example 1, Example 2, and the Comparative Example are shown in Table 1. Although there are differences in the thicknesses of the oxide semiconductor films between Examples 1 and 2 and the Comparative Example, the major differences are whether or not the aluminum oxide (AlOₓ) film is formed on the substrate, whether or not the substrate temperature was controlled during film formation, and the oxygen partial pressure.

TABLE 1

| | | Example | Example | Comparative |
|---|---|---|---|---|
| | | 1 | 2 | Example |
| Deposition | Formation of | Yes | Yes | No |
| conditions | AlOₓ | | | |
| | Substrate | Controlled | Controlled | Not |
| | temperature | to below | to below | controlled |
| | control | 100° C. | 100° C. | |
| | Oxygen partial | 5.1 | 5.1 | 10.0 |
| | pressure (%) | | | |
| | Thickness | 30 | 30 | 50 |
| | (nm) | | | |
| Annealing | Reached | 400 | 450 | 450 |
| conditions | temperature | | | |
| | (° C.) | | | |
| | Holding time | 30 | 60 | 60 |
| | (min) | | | |
| | atmosphere | air | air | air |

### 4-2. Crystal Structure Analysis by XRD Method

The crystal structures of the oxide semiconductor films of Examples 1 and 2 and the oxide semiconductor film of the Comparative Example were analyzed by an XRD method. The oxide semiconductor films of Examples 1 and 2 and the oxide semiconductor film of the Comparative Example all had crystallinity and had a bixbyite crystal structure.

### 4-3. Crystal Orientation Analysis Using EBSD Method

The crystal orientation of the oxide semiconductor films of Examples 1 and 2 and the oxide semiconductor film of the Comparative Example was analyzed by an EBSD method. The measurement conditions of the EBSD method are shown in Table 2. The crystal orientation was analyzed using OIM-Analysis (ver. 7.1) manufactured by TSL Solutions Co., Ltd. The determination of the crystal orientation of the crystal structure used the crystal structure file of the bixbyite structure 14388 of ICSD (Inorganic Crystal Structure Database: Association for Chemical Information). As a result of the measurement and analysis, when the CI value was greater than or equal to 0.6, it was determined that the obtained pattern was sufficiently clear and the crystal orientation was specified as the bixbyite structure.

TABLE 2

| | Thermal field emission scanning |
|---|---|
| | electron microscope (TFE-SEM) |
| | manufactured by JEOL Ltd. |
| Device | JSM-6500F |
| Acceleration | 10 kV |
| voltage | |
| Irradiation | 15 nA |
| current | |
| Sample tilt | 70 degrees |
| Measurement | 20 μm × 20 μm |
| region | |
| Measurement | 80 nm/step |
| interval | |

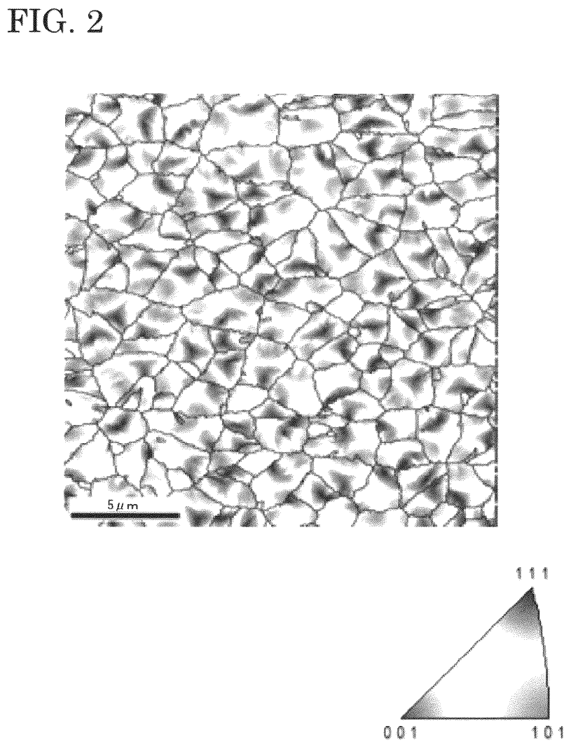

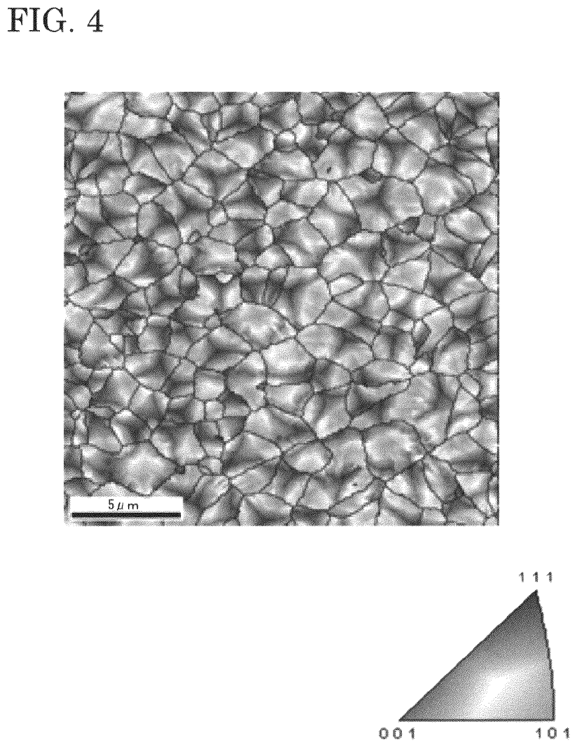

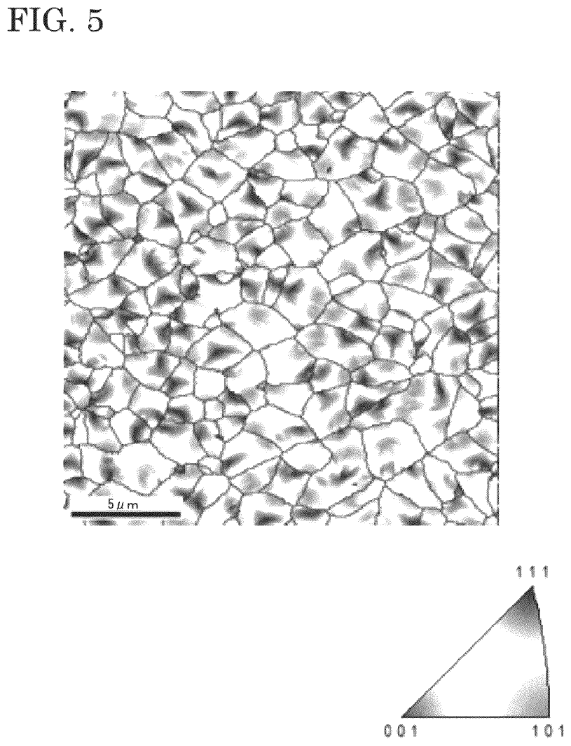

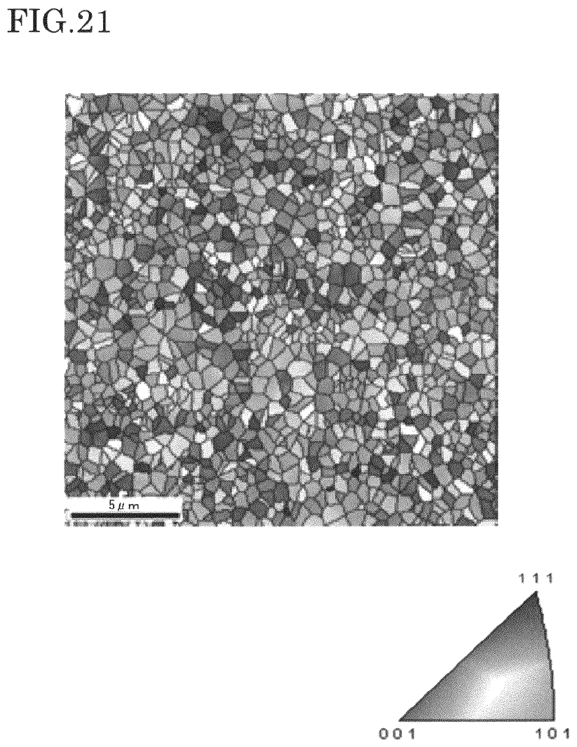

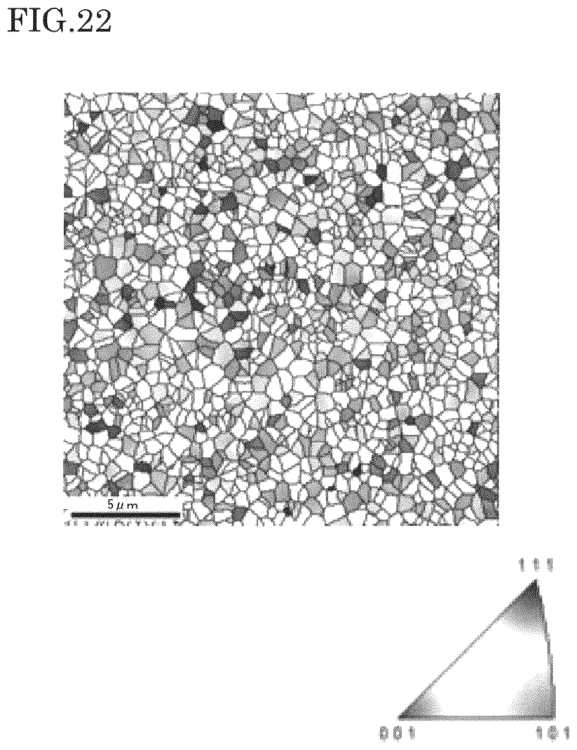

FIGS. 1 and 2 show the IPF maps of the oxide semiconductor film of Example 1. Further, FIGS. 4 and 5 show the IPF maps of the oxide semiconductor film of Example 2. Furthermore, FIGS. 21 and 22 show the IPF maps of the oxide semiconductor film of the Comparative Example. In FIGS. 1, 2, 4, 5, 21, and 22, black lines represent crystal grain boundaries. That is, a plurality of crystal grains surrounded by black lines can be confirmed in all the oxide semiconductor films of Examples 1 and 2 and the oxide semiconductor film of the Comparative Example. The IPF maps shown in FIGS. 1, 2, 4, 5, 21, and 22 are color-coded according to the color key shown in each figure. Mainly, the crystal orientation <001> is color-coded by red, the crystal orientation <101> is color-coded by green, and the crystal orientation <111> is color-coded by blue. In FIGS. 2, 5, and 22, measurement points that have the crystal orientation <001>, the crystal orientation <101>, or the crystal orientation <111> in the range of the crystal orientation difference from 0 degrees to 15 degrees with respect to the normal direction of the surface of the substrate (or the surface of the oxide semiconductor film) is in the range of are extracted and color-coded. In other words, FIGS. 2, 5, and 22 are images in which measurement points that have the crystal orientation <001>, the crystal orientation <101>, or the crystal orientation <111> in the range of the crystal orientation difference over 15 degrees with respect to the normal direction of the surface of the substrate are excluded from FIGS. 1, 4, and 21, respectively.

The average crystal grain sizes of the oxide semiconductor films of Examples 1 and 2 were calculated to be 1.94 μm and 1.96 μm, respectively. On the other hand, the average crystal grain size of the oxide semiconductor film of the Comparative Example was calculated to be 0.65 μm. The average crystal grain sizes of the oxide semiconductor films of Examples 1 and 2 were more than 2.5 times that of the oxide semiconductor film of the Comparative Example.

When the IPF maps shown in FIGS. 2 and 5 are compared with the IPF map shown in FIG. 22, the IPF map shown in FIG. 22 has many regions colored green, whereas the IPF maps shown in FIGS. 2 and 5 have many regions colored not only green but also blue. Based on FIG. 2 (i.e., measurement points having crystal orientations with the crystal orientation difference greater than or equal to 0 degrees and less than or equal to 15 degrees with respect to the normal direction of the surface of the substrate), the occupancy rates of the crystal orientation <001>, the crystal orientation <101>, and the crystal orientation <111> of the oxide semiconductor film of Example 1 in the measurement region were calculated to be 1.1%, 29.1%, and 29.3%, respectively. Further, based on FIG. 5 (i.e., measurement points having crystal orientations with the crystal orientation difference greater than or equal to 0 degrees and less than or equal to 15 degrees with respect to the normal direction of the surface of the substrate), the occupancy rates of the crystal orientation <001>, the crystal orientation <101>, and the crystal orientation <111> of the oxide semiconductor film of Example 2 in the measurement region were calculated to be 1.4%, 28.5%, and 27.5%, respectively. On the other hand, based on FIG. 22 (i.e., measurement points having crystal orientations with the crystal orientation difference greater than or equal to 0 degrees and less than or equal to 15 degrees with respect to the normal direction of the surface of the substrate), the occupancy rates of the crystal orientation <001>, the crystal orientation <101>, and the crystal orientation <111> of the oxide semiconductor film of the Comparative Example in the measurement region were calculated to be 5.6%, 23.3%, and 19.8%, respectively.

Further, the maximum crystal grain sizes of the oxide semiconductor films of Examples 1 and 2 were calculated to be 3.1 μm and 3.3 μm, respectively. On the other hand, the maximum crystal grain size of the oxide semiconductor film of the Comparative Example was calculated to be 1.1 μm. The maximum crystal grain sizes of the oxide semiconductor films of Examples 1 and 2 were about 3 times that of the oxide semiconductor film of the Comparative Example.

In the oxide semiconductor films of Examples 1 and 2, the occupancy rate of the crystal orientation <001> is lower than those of the crystal orientation <101> and the crystal orientation <111>. In other words, the occupancy rates of the crystal orientation <101> and the crystal orientation <111> is larger than that of the crystal orientation <001>. In the oxide semiconductor film of Example 1, the occupancy rates of the crystal orientation <101> and the crystal orientation <111> are 26.5 times and 26.6 times the occupancy rate of the crystal orientation <001>, respectively. Further, in the oxide semiconductor film of Example 2, the occupancy rates of the crystal orientation <101> and the crystal orientation <111> are 20.4 times and 16.6 times the occupancy rate of the crystal orientation <001>, respectively. On the other hand, in the oxide semiconductor film of the Comparative Example, the occupancy rates of the crystal orientation <101> and the crystal orientation <111> are 4.2 times and 3.5 times the occupancy rate of the crystal orientation <001>, respectively.

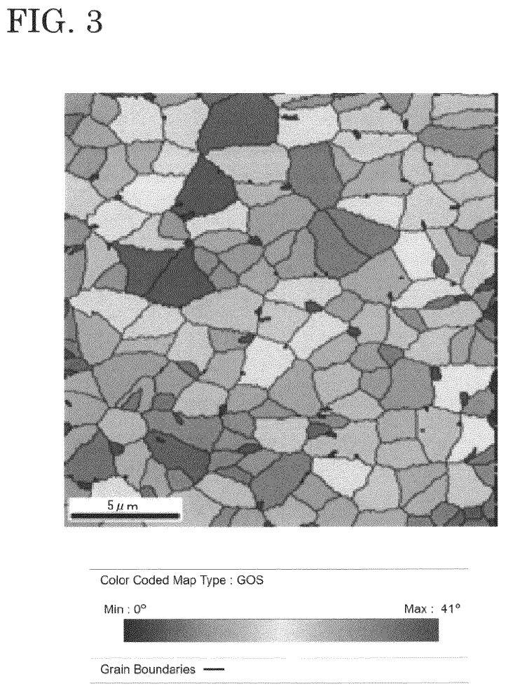

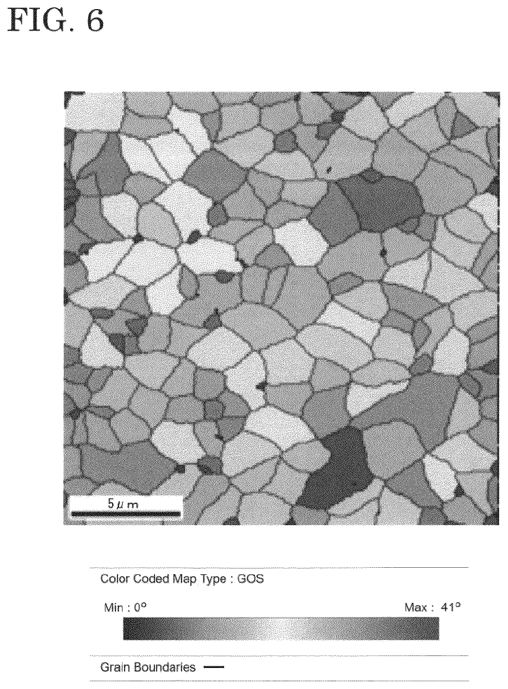

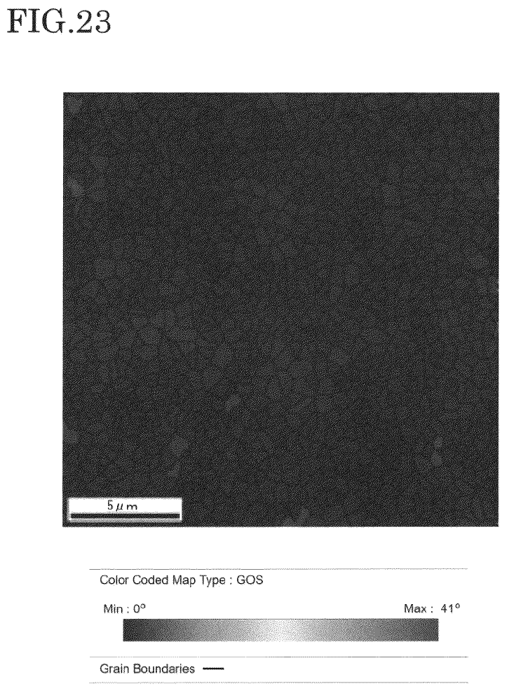

FIG. 3 shows a GOS distribution map in which a plurality of crystal grains are colored based on the GOS of each of the plurality of crystal grains included in the oxide semiconductor film of Example 1. FIG. 6 shows a GOS distribution map in which a plurality of crystal grains are colored based on the GOS of each of the plurality of crystal grains included in the oxide semiconductor film of Example 2. Further, FIG. 23 shows a GOS distribution map in which a plurality of crystal grains are colored based on the GOS of each of the plurality of crystal grains included in the oxide semiconductor film of the Comparative Example. In other words, FIGS. 3, 6, and 23 are distribution maps showing the magnitude of the crystal orientation difference in each of the crystal grains. In FIGS. 3, 6, and 23, the GOS of each of the plurality of crystal grains is colored based on the color bar shown in the figure, and the color of the crystal grain changes from blue to red. That is, as the visible light wavelength increases, the crystal orientation difference in the crystal grain increases.

When the GOS distribution maps shown in FIGS. 3 and 6 with the GOS distribution map shown in FIG. 23, all of the crystal grains are colored blue in the GOS distribution map shown in FIG. 23, whereas there are many crystal grains colored green, yellow, and red, and few crystal grains colored blue in the GOS distribution maps shown in FIGS. 3 and 6. Therefore, it has been found that the oxide semiconductor films of Example 1 and Example 2 include more crystal grains with a large change in crystal orientation than the oxide semiconductor film of the Comparative Example. Since a color gradation in the crystal grain can be confirmed in the IPF maps shown in also FIGS. 2 and 5, it can be seen that many crystal grains with a large change in crystal orientation are included in the oxide semiconductor film. Further, it has confirmed that the IPF maps shown in FIGS. 2 and 5 include crystal grains including two crystal orientations.

When the average GOS in the measurement region was calculated, the average GOS of the oxide semiconductor films of Examples 1 and 2 were 20.26 degrees and 19.28 degrees, respectively. On the other hand, the average GOS of the oxide semiconductor film of the Comparative Example was 0.71 degrees. It can also be seen from the average GOS that the change in crystal orientation in the crystal grain is significantly larger in the oxide semiconductor films of Examples 1 and 2 than in the oxide semiconductor film of the Comparative Example.

Table 3 shows information regarding the crystal structures of the oxide semiconductor films of Examples 1 and 2 and the oxide semiconductor film of the Comparative Example. As shown in Table 3, although the oxide semiconductor films of Examples 1 and 2 and the oxide semiconductor film of the Comparative Example have the same crystal structure which is a bixbyite structure, the crystal orientation features of the crystal grains included therein are significantly different.

TABLE 3

| | | | Comparative |
|---|---|---|---|
| | Example 1 | Example 2 | Example |
| Crystal structure | Bixbyite | Bixbyite | Bixbyite |
| | structure | structure | structure |
| Average crystal | 1.94 | 1.96 | 0.65 |
| grain size (μm) | | | |
| Maximum crystal | 3.1 | 3.3 | 1.1 |
| grain size (μm) | | | |
| Occupancy rate of | 1.1 | 1.4 | 5.6 |
| <001> crystal | | | |
| orientation (%) | | | |
| Occupancy rate of | 29.1 | 28.5 | 23.3 |
| <101> crystal | | | |
| orientation (%) | | | |
| Occupancy rate of | 29.3 | 27.5 | 19.8 |
| <111> crystal | | | |
| orientation (%) | | | |
| Average GOS | 20.26 | 19.28 | 0.71 |
| (degree) | | | |

As described above, the oxide semiconductor film according to the present embodiment has distinctive features in the crystal orientation of the crystal grains, and has a novel crystal structure different from that of the conventional oxide semiconductor film. Although the details are described later, a thin film transistor using the oxide semiconductor film according to the present embodiment has a higher field effect mobility than a thin film transistor using the conventional oxide semiconductor film. Therefore, it is presumed that the oxide semiconductor film according to the present embodiment itself also has a high mobility.

### Second Embodiment

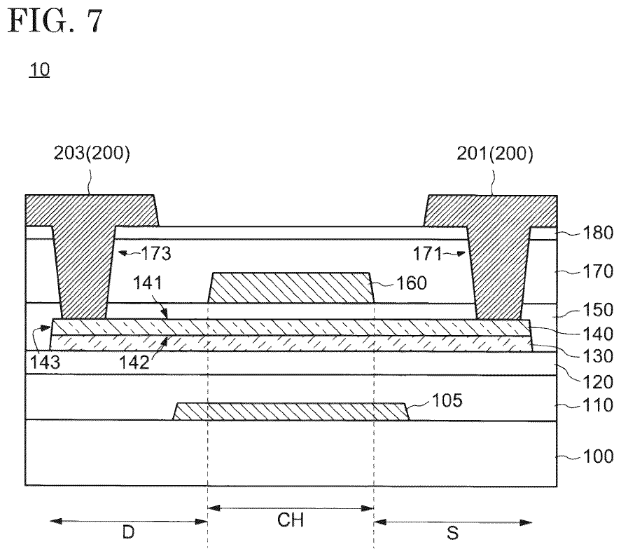

A thin film transistor according to an embodiment of the present embodiment is described with reference to FIGS. 7 to 17. For example, the thin film transistor according to the present embodiment can be used in a display device, an integrated circuit (IC) such as a microprocessor (Micro-Processing Unit: MPU), or a memory circuit.

### [1. Configuration of Thin Film Transistor 10]

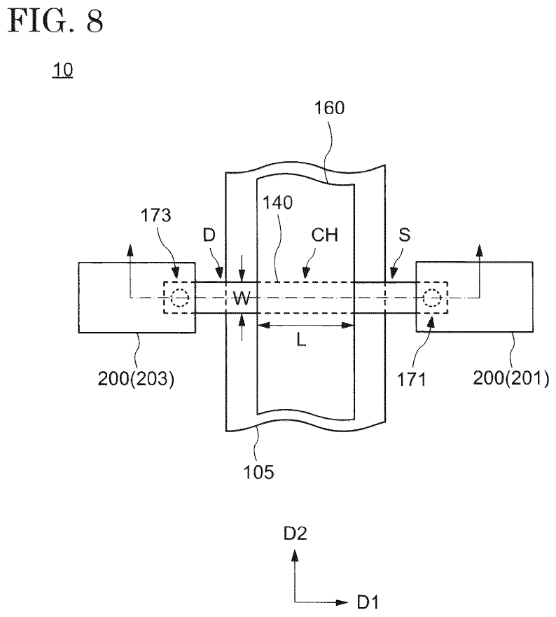

FIG. 7 is a cross-sectional view showing an overview of a thin film transistor 10 according to an embodiment of the present invention. FIG. 8 is a plan view showing an overview of the thin film transistor 10 according to an embodiment of the present invention.

As shown in FIG. 7, the thin film transistor 10 is provided over a substrate 100. The semiconductor device 10 includes a gate electrode 105, gate insulating layers 110 and 120, a metal oxide layer 130, an oxide semiconductor layer 140, a gate insulating layer 150, a gate electrode 160, insulating layers 170 and 180, a source electrode 201, and a drain electrode 203. When the source electrode 201 and the drain electrode 203 are not particularly distinguished from each other, they may be referred to as a source-drain electrode 200.

The gate electrode 105 is provided over the substrate 100. The gate insulating layers 110 and 120 are provided over the substrate 100 and the gate electrode 105. The metal oxide layer 130 is provided over the gate insulating layer 120. The metal oxide layer 130 is in contact with the gate insulating layer 120. The oxide semiconductor layer 140 is provided over the metal oxide layer 130. The oxide semiconductor layer 140 is in contact with the metal oxide layer 130. In the main surface of the oxide semiconductor layer 140, a surface in contact with the metal oxide layer 130 is referred to as a lower surface 142. An edge portion of the metal oxide layer 130 and an edge portion of the oxide semiconductor layer 140 are substantially aligned with each other.

In the thin film transistor 10 according to the present embodiment, a semiconductor layer or an oxide semiconductor layer is not provided between the metal oxide layer 130 and the substrate 100.

Although a configuration in which the metal oxide layer 130 is in contact with the gate insulating layer 120 is exemplified, the configuration is not limited to this configuration. Other layers may be provided between the gate insulating layer 120 and the metal oxide layer 130.

Although the side surface of the metal oxide layer 130 and the side surface of the oxide semiconductor layer 140 are aligned in a straight line in FIG. 7, the present invention is not limited to this configuration. The angle of the side surface of the metal oxide layer 130 with respect to the main surface of the substrate 100 may be different from the angle of the side surface of the oxide semiconductor layer 140. The cross-sectional shape of the side surface of at least one of the metal oxide layer 130 and the oxide semiconductor layer 140 may be curved.

The gate electrode 160 faces the oxide semiconductor layer 140. The gate insulating layer 150 is provided between the oxide semiconductor layer 140 and the gate electrode 160. The gate insulating layer 150 is in contact with the oxide semiconductor layer 140. In the main surface of the oxide semiconductor layer 140, a surface in contact with the gate insulating layer 150 is referred to as an upper surface 141. A surface between the upper surface 141 and the lower surface 142 is referred to as a side surface 143. The insulating layers 170 and 180 are provided over the gate insulating layer 150 and the gate electrode 160. Openings 171 and 173 in which the oxide semiconductor layer 140 is exposed are provided in the insulating layers 170 and 180. The source electrode 201 is provided so as to fill the inside of the opening 171. The source electrode 201 is in contact with the oxide semiconductor layer 140 at the bottom of the opening 171. The drain electrode 203 is provided so as to fill the inside of the opening 173. The drain electrode 203 is in contact with the oxide semiconductor layer 140 at the bottom of the opening 173.

The gate electrode 105 has a function as a bottom gate of the thin film transistor 10 and a function as a light shielding film for the oxide semiconductor layer 140. The gate insulating layer 110 has a function as a barrier film for shielding impurities that diffuse from the substrate 100 toward the oxide semiconductor layer 140. The gate insulating layers 110 and 120 have a function as a gate insulating layer for the bottom gate. The metal oxide layer 130 is a layer containing a metal oxide whose main component is aluminum, and not only improves the crystallinity of the oxide semiconductor layer 140 but also has a function as a gas barrier film that blocks gases such as oxygen and hydrogen.

The oxide semiconductor layer 140 is divided into a source region S, a drain region D, and a channel region CH. The channel region CH is a region of the oxide semiconductor layer 140 vertically below the gate electrode 160. The source region S is a region of the oxide semiconductor layer 140 that does not overlap the gate electrode 160 and is closer to the source electrode 201 than the channel region CH. The drain region D is a region of the oxide semiconductor layer 140 that does not overlap the gate electrode 160 and is closer to the drain electrode 203 than the channel region CH. The oxide semiconductor layer 140 in the channel region CH has physical properties as a semiconductor. The oxide semiconductor layer 140 in the source region S and the drain region D has physical properties as a conductor.

The gate electrode 160 has a function as a top gate of the thin film transistor 10 and a light shielding film for the oxide semiconductor layer 140. The gate insulating layer 150 has a function as a gate insulating layer for the top-gate, and has a function of releasing oxygen by a heat treatment in a manufacturing process. The insulating layers 170 and 180 insulate the gate electrode 160 and the source-drain electrode 200 and have a function of reducing parasitic capacitance therebetween. Operations of the thin film transistor 10 are controlled mainly by a voltage supplied to the gate electrode 160. An auxiliary voltage is supplied to the gate electrode 105. However, in the case of using the gate electrode 105 simply as a light shielding film, a specific voltage is not supplied to the gate electrode 105, and the gate electrode 105 may be in a floating state. That is, the gate electrode 105 may simply be referred to as a “light shielding film.”

In the present embodiment, although a configuration using a dual gate transistor in which the gate electrode is provided both over and below the oxide semiconductor layer as the thin film transistor 10 is exemplified, the configuration is not limited to this configuration. For example, a bottom gate transistor in which the gate electrode is provided only below the oxide semiconductor layer 140 or a top gate transistor in which the gate electrode is provided only over the oxide semiconductor layer 140 may be used as the thin film transistor 10. The above configuration is merely an embodiment, and the present invention is not limited to the above configuration.

As shown in FIG. 8, a planar pattern of the metal oxide layer 130 is substantially the same as a planar pattern of the oxide semiconductor layer 140 in a plan view. The lower surface 142 of the oxide semiconductor layer 140 is covered with the metal oxide layer 130 with reference to FIGS. 7 and 8. In particular, in the present embodiment, all of the lower surface 142 of the oxide semiconductor layer 140 is covered with the metal oxide layer 130. A width of the gate electrode 105 is greater than a width of the gate electrode 160 in a direction D1. The direction D1 is a direction connecting the source electrode 201 and the drain electrode 203, and is a direction representing a channel length L of the thin film transistor 10. Specifically, a length in the direction D1 of the region (the channel region CH) where the oxide semiconductor layer 140 and the gate electrode 160 overlap is the channel length L, and a width in a direction D2 in the channel region CH is a channel width W.

In the present embodiment, although a configuration in which all of the lower surface 142 of the oxide semiconductor layer 140 is covered with the metal oxide layer 130 is exemplified, the present invention is not limited to this configuration. For example, a part of the lower surface 142 of the oxide semiconductor layer 140 may not be in contact with the metal oxide layer 130. For example, all of the lower surface 142 of the oxide semiconductor layer 140 in the channel region CH may be covered with the metal oxide layer 130, and all or part of the lower surface 142 of the oxide semiconductor layer 140 in the source region S and the drain region D may not be covered with the metal oxide layer 130. That is, all or part of the lower surface 142 of the oxide semiconductor layer 140 in the source region S and the drain region D may not be in contact with the metal oxide layer 130. However, in the above configuration, a part of the lower surface 142 of the oxide semiconductor layer 140 in the channel region CH may not be covered with the metal oxide layer 130, and the other part of the lower surface 142 may be in contact with the metal oxide layer 130.

In the present embodiment, although a configuration in which the gate insulating layer 150 is formed on the entire surface and the openings 171 and 173 are provided in the gate insulating layer 150 is exemplified, the configuration is not limited to this configuration. The gate insulating layer 150 may be patterned. For example, the gate insulating layer 150 may be patterned to expose not only the upper surface but also the side surfaces of the oxide semiconductor layer 140.

In FIG. 8, although a configuration in which the source-drain electrode 200 does not overlap the gate electrode 105 and 160 in a plan view is exemplified, the configuration is not limited to this configuration. For example, in a plan view, the source-drain electrode 200 may overlap at least one of the gate electrodes 105 and 160. The above configuration is merely an embodiment, and the present invention is not limited to the above configuration.

### [2. Material of Each Member of Thin Film Transistor 10]

A rigid substrate having translucency, such as a glass substrate, a quartz substrate, a sapphire substrate, or the like, is used as the substrate 100. In the case where the substrate 100 needs to have flexibility, a substrate containing a resin such as a polyimide substrate, an acryl substrate, a siloxane substrate, or a fluororesin substrate is used as the substrate 100. In the case where the substrate containing a resin is used as the substrate 100, impurities may be introduced into the resin in order to improve the heat resistance of the substrate 100. In the case where the thin film transistor 10 is a pixel transistor included in a display device such as a top emission OLED, since the substrate 100 does not need to be transparent, impurities that reduces the translucency of the substrate 100 may be used. In the case where the thin film transistor 10 is used for an integrated circuit that is not a display device, a substrate without translucency such as a semiconductor substrate such as a silicon substrate, a silicon carbide substrate, a compound semiconductor substrate, or a conductive substrate such as a stainless substrate is used as the substrate 100.

Common metal materials are used for the gate electrode 105, the gate electrode 160, and the source-drain electrode 200. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof are used as these members. The above-described materials may be used in a single layer or in a stacked layer as the gate electrode 105, the gate electrode 160, and the source-drain electrode 200.

Common insulating materials are used for the gate insulating layers 110 and 120 and the insulating layers 170 and 180. For example, inorganic insulators such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), and aluminum nitride (AlNₓ) are used as the insulating materials.

An insulator containing oxygen among the above-described insulating materials is used for the gate insulating layer 150. For example, an inorganic insulator such as silicon oxide (SiOₓ), silicon oxynitride (SiOₓN_{y}), aluminum oxide (AlOₓ), or aluminum oxynitride (AlOₓN_{y}) is used for the gate insulating layer 150.

An insulator having a function of releasing oxygen by a heat treatment is used for the gate insulating layer 120. For example, the temperature of the heat treatment at which the gate insulating layer 120 releases oxygen is less than or equal to 600° C., less than or equal to 500° C., less than or equal to 450° C., or less than or equal to 400° C. That is, the gate insulating layer 120 releases oxygen at the heat treatment temperature performed in the manufacturing process of the thin film transistor 10 in the case where the glass substrate is used as the substrate 100, for example.

An insulating layer with few deficiencies is used as the gate insulating layer 150. For example, when a composition ratio of oxygen in the gate insulating layer 150 is compared with a composition ratio of oxygen in an insulating layer (hereinafter, referred to as “other insulating layer”) having a composition similar to that of the gate insulating layer 150, the composition ratio of oxygen in the gate insulating layer 150 is closer to the stoichiometric ratio with respect to the insulating layer than the composition ratio of oxygen in that other insulating layer. Specifically, in the case where silicon oxide (SiOₓ) is used for each of the gate insulating layer 150 and the insulating layer 180, the composition ratio of oxygen in the silicon oxide used as the gate insulating layer 150 is close to the stoichiometric ratio of silicon oxide as compared with the composition ratio of oxygen in the silicon oxide used as the insulating layer 180. For example, a layer in which few deficiencies are observed when evaluated by the electron spin resonance (ESR) may be used as the gate insulating layer 150.

SiOₓN_{y} and AlOₓN_{y} described above are a silicon compound and an aluminum compound containing nitrogen (N) in a ratio (x>y) smaller than that of oxygen (O). SiNₓO_{y} and AlNₓO_{y} are a silicon compound and an aluminum compound containing oxygen in a ratio (x>y) smaller than that of nitrogen.

A metal oxide containing aluminum as the main component is used for the metal oxide layer 130. For example, an inorganic insulator such as aluminum oxide (AlOₓ), aluminum oxynitride (AlOₓN_{y}), aluminum nitride oxide (AlNₓO_{y}), or aluminum nitride (AlNₓ) is used for the metal oxide layer 130. The “metal oxide layer containing aluminum as the main component” means that the ratio of aluminum contained in the metal oxide layer 130 is greater than or equal to 1% of the total amount of the metal oxide layer 130. The ratio of aluminum contained in the metal oxide layer 130 may be greater than or equal to 5% and less than or equal to 70%, greater than or equal to 10% and less than or equal to 60%, or greater than or equal to 30% and less than or equal to 50% of the total amount of the metal oxide layer 130. The above ratio may be a mass ratio or a weight ratio.

The oxide semiconductor film according to the First Embodiment can be used as the oxide semiconductor layer 140. The oxide semiconductor layer 140 has crystallinity. Oxygen deficiencies are less likely to form in a crystalline oxide semiconductor than in an amorphous oxide semiconductor. However, the crystal grain boundaries of the oxide semiconductor layer 140 may include amorphous regions.

In addition, the metal oxide layer 130 and the oxide semiconductor layer 140 may contain a metal element common to each other. That is, the metal oxide layer 130 may contain a metal element other than indium contained in the oxide semiconductor layer 140.

### [3. Manufacturing Method of Thin Film Transistor 10]

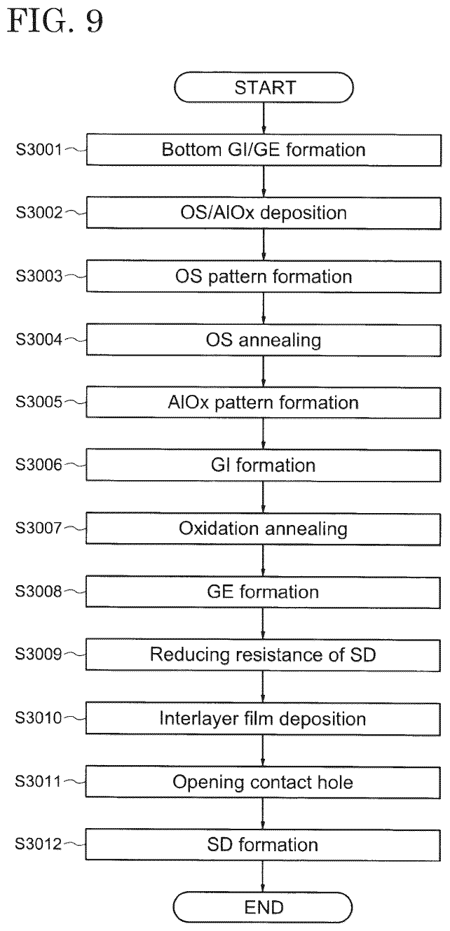

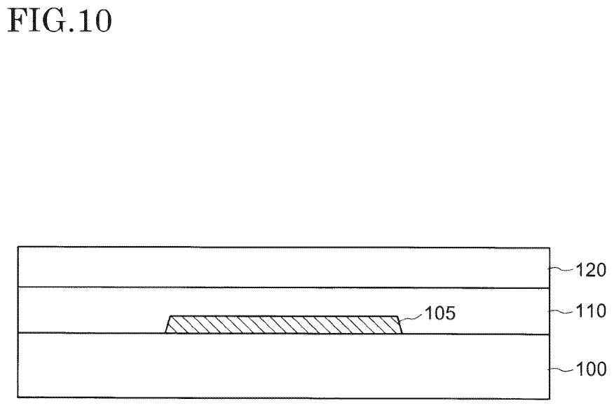

FIG. 9 is a flowchart showing a method for manufacturing the thin film transistor 10 according to an embodiment of the present embodiment. FIGS. 10 to 17 are cross-sectional views showing the method for manufacturing the thin film transistor 10 according to an embodiment of the present embodiment.

As shown in FIGS. 9 and 10, the gate electrode 105 is formed as a bottom gate on the substrate 100, and gate insulating layers 110 and 120 are formed on the gate electrode 105 (step S3001 “Bottom GI/GE formation” in FIG. 9). For example, silicon nitride is formed for the gate insulating layer 110. For example, silicon oxide is formed for the gate insulating layer 120. The gate insulating layers 110 and 120 are formed by a CVD (Chemical Vapor Deposition) method.

When silicon nitride is used for the gate insulating layer 110, the gate insulating layer 110 can block impurities that diffuse, for example, from the substrate 100 toward the oxide semiconductor layer 140. The silicon oxide used for the gate insulating layer 120 is silicon oxide having a physical property of releasing oxygen by a heat treatment.

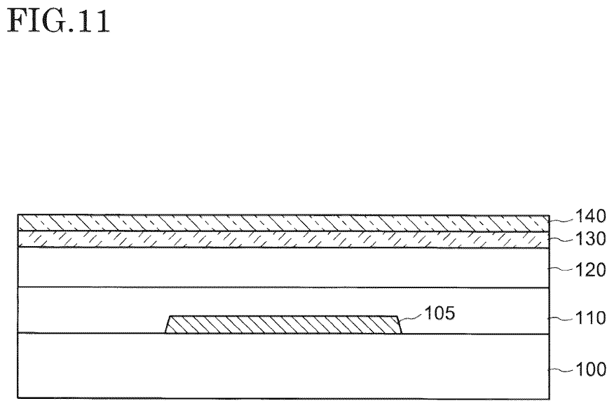

As shown in FIGS. 9 and 11, a metal oxide layer 130 and an oxide semiconductor layer 140 are formed on a gate insulating layer 120 (step S3002 “OS/AlOₓ formation” in FIG. 9). The metal oxide layer 130 is deposited by a sputtering method or an atomic layer deposition (ALD) method. The oxide semiconductor layer 140 is deposited by a sputtering method.

For example, a thickness of the metal oxide layer 130 is greater than or equal to 1 nm and less than or equal to 100 nm, greater than or equal to 1 nm and less than or equal to 50 nm, greater than or equal to 1 nm and less than or equal to 30 nm, or greater than or equal to 1 nm and less than or equal to 10 nm. In the present embodiment, aluminum oxide is used for the metal oxide layer 130. Aluminum oxide has a high barrier property against gas. In the present embodiment, since the aluminum oxide used for the metal oxide layer 130 blocks hydrogen and oxygen, the metal oxide layer 130 suppresses the hydrogen and oxygen released from the gate insulating layer 120 from reaching the oxide semiconductor layer 140. Further, the metal oxide layer 130 improves the crystallinity of the oxide semiconductor layer 140.

For example, a thickness of the oxide semiconductor layer 140 is greater than or equal to 10 nm and less than or equal to 100, greater than or equal to 15 nm and less than or equal to 70 nm, or greater than or equal to 20 nm and less than or equal to 40 nm. The oxide semiconductor layer 140 before the heat treatment (OS annealing) described later is amorphous.

When the oxide semiconductor layer 140 is crystallized by the OS annealing described later, it is preferable that the oxide semiconductor layer 140 after the deposition and before the OS annealing is in an amorphous state (a state in which there are less low crystalline components of the oxide semiconductor). That is, the deposition conditions of the oxide semiconductor layer 140 are preferred to be such that the oxide semiconductor layer 140 immediately after the deposition does not crystallize as much as possible. For example, when the oxide semiconductor layer 140 is deposited by the sputtering method, the oxide semiconductor layer 140 is deposited in a state where the temperature of the object to be deposited (the substrate 100 and structures formed thereon) is controlled below 100° C. Further, the oxide semiconductor layer 140 is deposited under the condition in which the oxygen partial pressure is less than or equal to 10%.

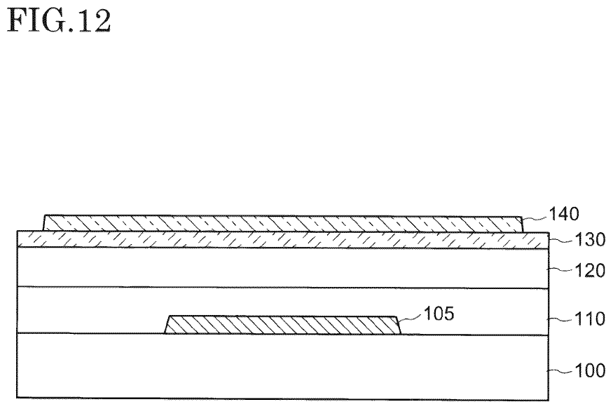

As shown in FIGS. 9 and 12, a pattern of the oxide semiconductor layer 140 is formed (step S3003 “OS pattern formation” in FIG. 9). Although not shown in the figures, a resist mask is formed on the oxide semiconductor layer 140, and the oxide semiconductor layer 140 is etched using the resist mask. Wet etching may be used, or dry etching may be used to etch the oxide semiconductor layer 140. The wet etching can perform using an acidic etchant. For example, oxalic acid or hydrofluoric acid can be used as the etchant.

A heat treatment (OS annealing) (step S3004 “OS annealing” in FIG. 9) is performed on the oxide semiconductor layer 140 after the pattern of the oxide semiconductor layer 140 is formed. In the present embodiment, the oxide semiconductor layer 140 is crystallized by the OS annealing.

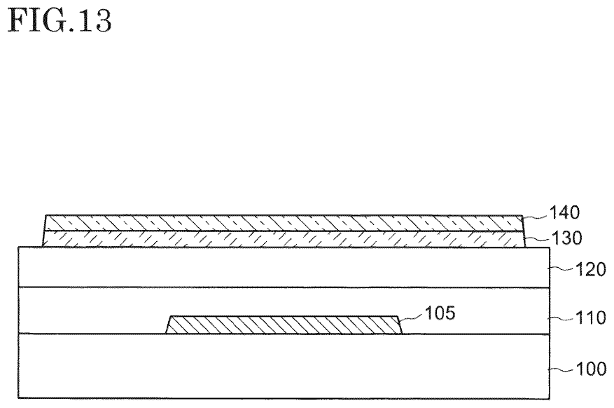

As shown in FIGS. 9 and 13, a pattern of the metal oxide layer 130 is formed (step S3005 “AlOₓ pattern formation” in FIG. 3). The metal oxide layer 130 is etched using the oxide semiconductor layer 140 patterned in the above process as a mask. Wet etching may be used, or dry etching may be used as the etching method of the metal oxide layer 130. For example, dilute hydrofluoric acid (DHF) is used for the wet etching. As described above, a photolithography process can be omitted by etching the metal oxide layer 130 using the oxide semiconductor layer 140 as the mask.

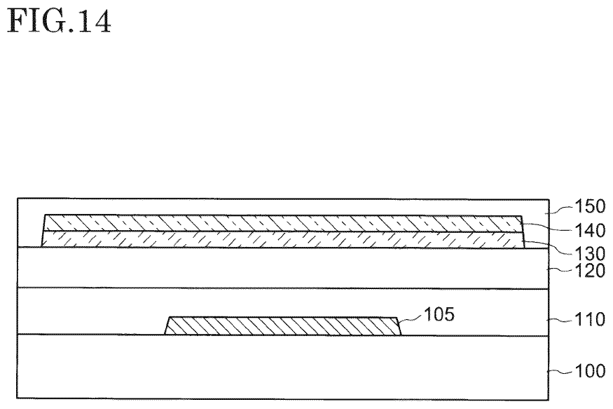

As shown in FIG. 9 and FIG. 14, the gate insulating layer 150 is deposited on the oxide semiconductor layer 140 (step S3006 “GI formation” in FIG. 9). For example, silicon oxide is formed for the gate insulating layer 150. The gate insulating layer 150 is formed by a CVD method. For example, the gate insulating layer 150 may be deposited at a deposition temperature higher than or equal to 350° C. in order to form an insulating layer having few deficiencies as described above as the gate insulating layer 150. For example, the thickness of the gate insulating layer 150 is greater than or equal to 50 nm and less than or equal to 300 nm, greater than or equal to 60 nm and less than or equal to 200 nm, or greater than or equal to 70 nm and less than or equal to 150 nm. A process of implanting oxygen may be performed on a part of the gate insulating layer 150 after the gate insulating layer 150 is deposited.

A heat treatment (oxidation annealing) is performed in a state where the gate insulating layer 150 is deposited on the oxide semiconductor layer 140 in order to supply oxygen to the oxide semiconductor layer 140 (step S3007 “Oxidation annealing” in FIG. 9). During the process from depositing the oxide semiconductor layer 140 to depositing the gate insulating layer 150 on the oxide semiconductor layer 140, many oxygen deficiencies are generated on the upper surface 141 and the side surfaces 143 of the oxide semiconductor layer 140. When the above-described oxidation annealing is performed, oxygen released from the gate insulating layers 120 and 150 is supplied to the oxide semiconductor layer 140, and the oxygen deficiencies are repaired.

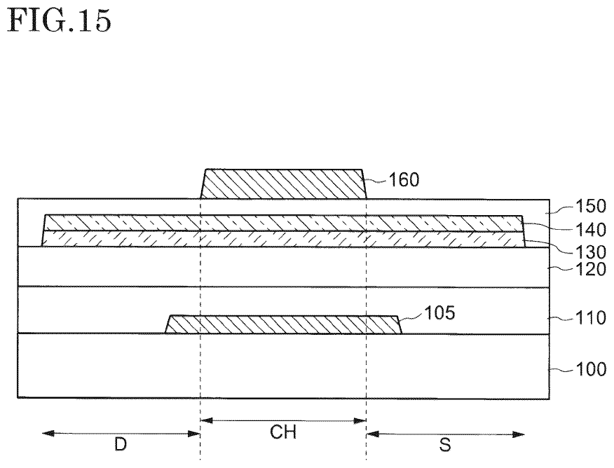

As shown in FIGS. 9 and 15, the gate electrode 160 is deposited (step S3007 “GE formation” in FIG. 9). The gate electrode 160 is deposited by a sputtering method or an atomic layer deposition method and patterned through a photolithography process.

Resistances of the source region S and the drain region D of the oxide semiconductor layer 140 are reduced (step S3009 “Reducing resistance of SD” in FIG. 9) in a state where the gate electrode 160 is patterned. Specifically, impurities are implanted into the oxide semiconductor layer 140 from the gate electrode 160 side through the gate insulating layer 150 by ion implantation. For example, argon (Ar), phosphorus (P), and boron (B) are implanted into the oxide semiconductor layer 140 by the ion implantation. Since oxygen deficiencies are generated in the oxide semiconductor layer 140 by the ion implantation, the resistance of the oxide semiconductor layer 140 is reduced. Since the gate electrode 160 is provided over the oxide semiconductor layer 140 functioning as the channel region CH of the thin film transistor 10, impurities are not implanted into the oxide semiconductor layer 140 in the channel region CH.

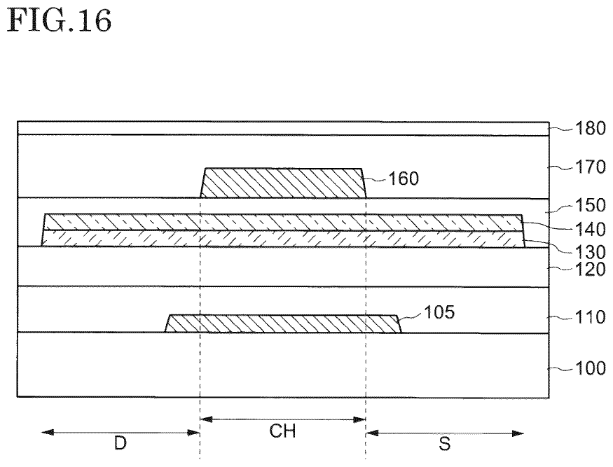

As shown in FIGS. 9 and FIG. 16, the insulating layers 170 and 180 are deposited on the gate insulating layer 150 and the gate electrode 160 as interlayer films (step S3010 “Interlayer film deposition” in FIG. 9). The insulating layers 170 and 180 are deposited by a CVD method. For example, silicon nitride is formed for the insulating layer 170, and silicon oxide is formed for the insulating layer 180. The materials used for the insulating layers 170 and 180 are not limited thereto. A thickness of the insulating layer 170 is greater than or equal to 50 nm and greater than or equal to 500 nm. A thickness of the insulating layer 180 is greater than or equal to 50 nm and less than or equal to 500 nm.

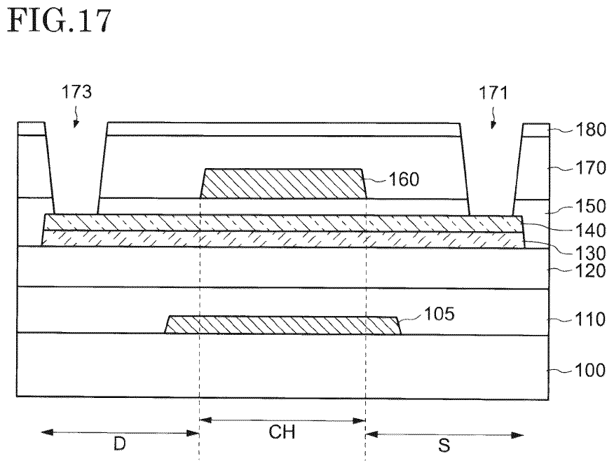

As shown in FIGS. 9 and 17, the openings 171 and 173 are formed in the gate insulating layer 150 and the insulating layers 170 and 180 (step S3011 “Opening contact hole” in FIG. 9). The oxide semiconductor layer 140 in the source region S is exposed by the opening 171. The oxide semiconductor layer 140 in the drain region D is exposed by the opening 173. The thin film transistor 10 shown in FIG. 7 is completed by forming the source-drain electrode 200 on the oxide semiconductor layer 140 exposed by the openings 171 and 173 and on the insulating layer 180 (step S3012 “SD formation” in FIG. 9).

In the thin film transistor 10 manufactured by the above-described manufacturing method, it is possible to obtain electrical characteristics having a mobility higher than or equal to 30 cm²/Vs, higher than or equal to 35 cm²/Vs, or higher than or equal to 40 cm²/Vs in a range where the channel length L of the channel region CH is greater than or equal to 2 μm and less than or equal to 4 μm and the channel width of the channel region CH is greater than or equal to 2 μm and less than or equal to 25 μm. In addition, the mobility in the present embodiment is the field-effect mobility in a saturation region and means the largest value of the field-effect mobility in a region where a potential difference (Vd) between the source electrode and the drain electrode is greater than a value (Vg-Vth) obtained by subtracting a threshold-voltage (Vth) of the thin film transistor 10 from a voltage (Vg) supplied to the gate electrode.

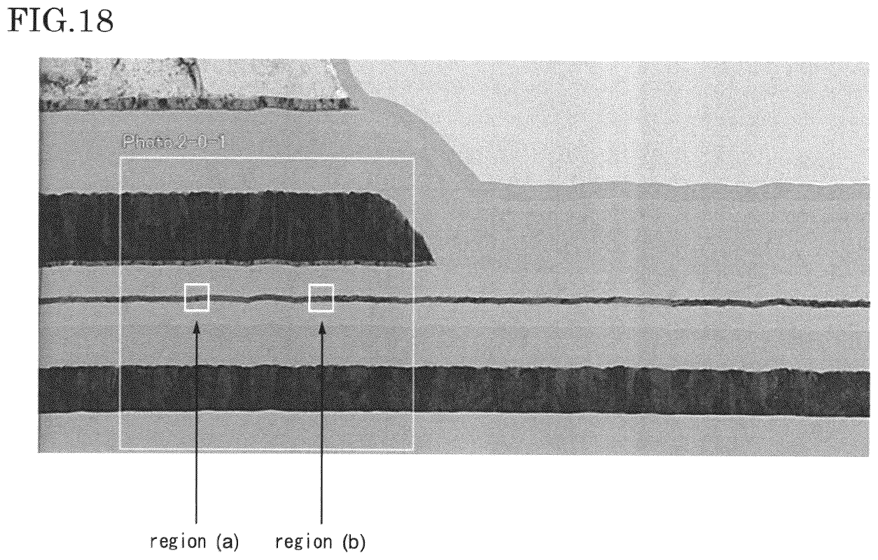

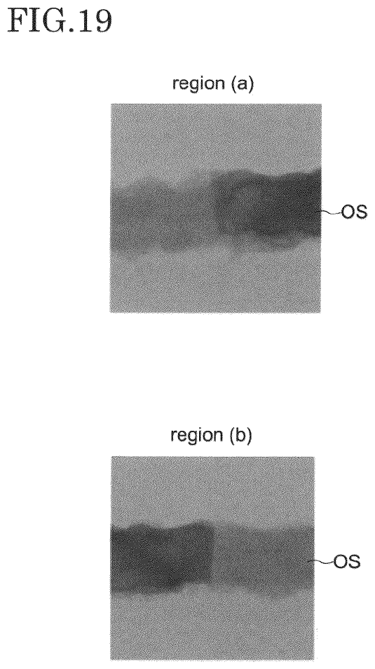

Further, a cross-sectional scanning transmission electron microscopy (STEM) observation was performed on the thin film transistor 10 manufactured by the above-described manufacturing method. FIGS. 18 and 19 are cross-sectional STEM images of the thin film transistor 10 according to an embodiment of the present embodiment. Regions (a) and (b) surrounded by rectangles in FIG. 18 are regions including the oxide semiconductor layer OS, and FIG. 19 is a cross-sectional STEM image in which the regions (a) and (b) are enlarged.

As shown in FIG. 19, although crystal grain boundaries in the oxide semiconductor layer OS can be confirmed in an in-plane direction in both of the regions (a) and (b), no crystal grain boundaries in the oxide semiconductor layer OS can be confirmed in the thickness direction. That is, a part of the upper surface and a part of the lower surface of the oxide semiconductor layer OS are formed by one crystal grain in at least some regions of the oxide semiconductor layer OS. In other words, the oxide semiconductor layer OS has a continuous crystal structure in the thickness direction.

### Third Embodiment

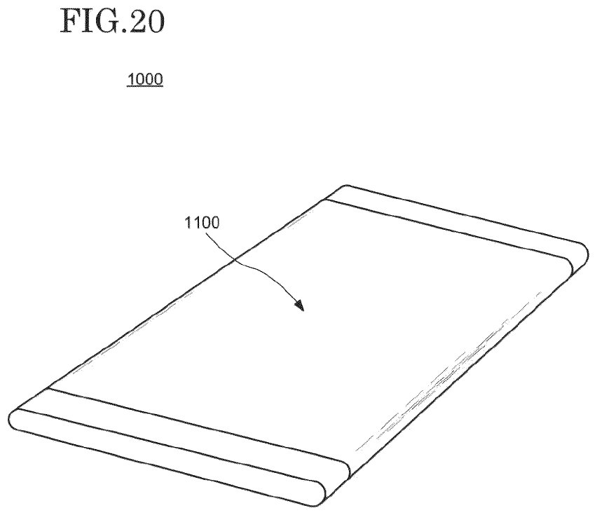

An electronic device according to an embodiment of the present embodiment is described with reference to FIG. 20.

FIG. 20 is a schematic diagram showing an electronic device 1000 according to an embodiment of the present embodiment. Specifically, FIG. 20 shows a smartphone, which is an example of the electronic device 1000. The electronic device 1000 includes a display device 1100 with curved sides. The display device 1100 includes a plurality of pixels for displaying an image. The plurality of pixels are controlled by a pixel circuit, a drive circuit, and the like. The pixel circuit and the drive circuit include the thin film transistor 10 described in the Second Embodiment. Since the thin film transistor 10 has high field effect mobility, the responsiveness of the pixel circuit and the drive circuit can be improved, and as a result, the performance of the electronic device 1000 can be improved.

The electronic device 1000 according to the present embodiment is not limited to a smartphone. For example, the electronic device 1000 also includes an electronic device having a display device, such as a watch, a tablet, a notebook computer, a car navigation system, or a television. The oxide semiconductor film described in the First Embodiment or the thin film transistor 10 described in the Second Embodiment can be applied to any electronic device, regardless of whether or not the electronic device has a display device.

Each of the embodiments described above as the embodiment of the present invention can be appropriately combined and implemented as long as no contradiction is caused. Further, the addition, deletion, or design change of components, or the addition, deletion, or condition change of processes as appropriate by those skilled in the art based on each of the embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A thin film transistor provided over a substrate, comprising:
a metal oxide layer over the substrate;
an oxide semiconductor layer having crystallinity in contact with the metal oxide layer;
a gate electrode overlapping the oxide semiconductor layer; and
an insulating layer between the oxide semiconductor layer and the gate electrode,
wherein the oxide semiconductor layer comprises a plurality of crystal grains, each of the plurality of crystal grains comprising at least one of a crystal orientation <001>, a crystal orientation <101>, and a crystal orientation <111> obtained by an electron backscatter diffraction (EBSD) method, and
wherein in occupancy rates of crystal orientations calculated based on measurement points having crystal orientations with a crystal orientation difference greater than or equal to 0 degrees and less than or equal to 15 degrees with respect to a normal direction of a surface of the substrate, an occupancy rate of the crystal orientation <001> is less than or equal to 5%.

2. The thin film transistor according to claim 1, wherein an occupancy rate of the crystal orientation <101> is greater than or equal to 4 times the occupancy rate of the crystal orientation <001>.

3. The thin film transistor according to claim 1, wherein an occupancy rate of the crystal orientation <111> is greater than or equal to 4 times the occupancy rate of the crystal orientation <001>.

4. The thin film transistor according to claim 1, wherein a ratio of an occupancy rate of the crystal orientation <101> to an occupancy rate of the crystal orientation <111> is greater than or equal to 0.7 and less than or equal to 1.5.

5. The thin film transistor according to claim 1, wherein at least one of the plurality of crystal grains comprises at least two of the crystal orientation <001>, the crystal orientation <101>, and the crystal orientation <111>.

6. The thin film transistor according to claim 1, wherein an average GOS of the plurality of crystal grains is greater than or equal to 5 degrees.

7. The thin film transistor according to claim 1, wherein an average crystal grain size of the plurality of crystal grains is greater than or equal to 1 μm.

8. The thin film transistor according to claim 1, wherein a maximum crystal grain size of the plurality of crystal grains is greater than or equal to 2 μm.

9. The thin film transistor according to claim 1,
wherein the oxide semiconductor layer comprises indium and at least one or more metal elements, and
wherein a ratio of the indium to all metal elements including the indium in the oxide semiconductor layer is greater than or equal to 50%.

10. The thin film transistor according to claim 9, wherein the metal oxide layer comprises one of the at least one or more metal elements.

11. The thin film transistor according to claim 1, wherein the metal oxide layer comprises aluminum oxide.

12. The thin film transistor according to claim 1, wherein the oxide semiconductor layer is deposited while a substrate temperature lower than or equal to 50° C. is controlled during deposition.

13. The thin film transistor according to claim 12, wherein the oxide semiconductor layer is deposited under an oxygen partial pressure less than or equal to 10%.

14. The thin film transistor according to claim 13, wherein the oxide semiconductor layer is crystallized by annealing after deposition.

15. The thin film transistor according to claim 14, wherein the oxide semiconductor layer is annealed at a reaching temperature higher than or equal to 350° C. and lower than or equal to 450° C.

16. An electronic device comprising the thin film transistor according to claim 1.
